(19) United States
(12) Patent Application Publication
(10) Pub. No.: US 2020/0144303 A1
(43) Pub. Date: May 7, 2020

(54) THIN FILM TRANSISTOR SUBSTRATE AND METHOD FOR PRODUCING THIN FILM TRANSISTOR SUBSTRATE

(71) Applicant: V TECHNOLOGY CO., LTD., Kanagawa (JP)

(72) Inventors: Koichi KAJIYAMA, Kanagawa (JP); Michinobu MIZUMURA, Kanagawa (JP)

(21) Appl. No.: 16/734,652

(22) Filed: Jan. 6, 2020

Related U.S. Application Data
(63) Continuation of application No. PCT/JP2018/025209, filed on Jul. 3, 2018.

(30) Foreign Application Priority Data
Jul. 10, 2017 (JP) 2017-134579

(51) Int. Cl. H01L 27/12; H01L 23/544

(52) U.S. Cl. CPC H01L 27/1218; H01L 2223/54426; H01L 23/544; H01L 27/1262

(57) ABSTRACT

Cracking or chipping in a substrate can be prevented while improving durability of a TFT with respect to external force caused by bending, winding, and the like. In a flexible substrate, a recessed portion is formed in a second surface opposite to a first surface in which a thin film transistor is formed, and the recessed portion is disposed at a position not overlapping with the thin film transistor as viewed in a first direction substantially orthogonal to the first surface.

### CROSS-REFERENCE TO RELATED APPLICATIONS

This application is a continuation application of International Patent Application No. PCT/JP2018/025209 filed on Jul. 3, 2018, which claims priority to Japanese Patent Application No. 2017-134579 filed on Jul. 10, 2017, the entire contents of which are incorporated by reference.

### TECHNICAL FIELD

The present invention relates to a thin film transistor substrate and a method for producing a thin film transistor substrate.

### BACKGROUND ART

Patent Document 1 discloses a thin film transistor array substrate for driving a flexible display, and the thin film transistor array substrate secures high curvature resistance regardless of a semiconductor material by forming, in a plastic substrate, a buffer layer that has an island shape and relieves stress and by forming a TFT in an upper portion of the buffer layer.

### CITATION LIST

### Patent Document

Patent Document 1: JP 2014-138179 A

In the invention described in Patent Document 1, a material of the plastic substrate and a material of the buffer layer are different from each other, and thus there is a possibility that inner stress is generated in the thin film transistor array substrate due to change in temperature or the like. Further, the buffer layer is provided in the plastic substrate, and thus when the thin film transistor array substrate is bent, force is liable to be applied to a boundary portion between the plastic substrate and the buffer layer. As a result, there is a risk of peeling off of the buffer layer from the plastic substrate and generation of cracking or chipping in the thin film transistor array substrate.

### SUMMARY OF INVENTION

One or more embodiments of the present invention are directed to a thin film transistor substrate and a method for producing the thin film transistor substrate that can prevent cracking or chipping in a substrate while improving durability of a thin film transistor (TFT) with respect to external force caused by bending, winding, and the like.

A thin film transistor substrate according to one or more embodiments of the present invention include, for example, a flexible substrate; and a thin film transistor provided in a first surface of the flexible substrate. A recessed portion is formed in a second surface opposite to the first surface of the flexible substrate. The recessed portion is disposed at a position not overlapping with the thin film transistor as viewed in a first direction substantially orthogonal to the first surface.

According to the thin film transistor substrate according to one or more embodiments of the present invention, the recessed portion is formed at the position not overlapping with the thin film transistor of the flexible substrate. Thus, the thickness of the flexible substrate at the position not overlapping with the TFT is smaller than the thickness of the flexible substrate at the position overlapping with the TTF. Therefore, a portion where the flexible substrate has a small thickness first curves, and deformation of the flexible substrate at the position overlapping with the TFT is suppressed. Accordingly, durability of the TFT with respect to external force caused by bending, winding, and the like can be improved. Further, the recessed portion is formed, and accordingly a portion of the flexible substrate is easily pliable. Thus, cracking or chipping of the substrate due to inner stress or difference in a coefficient of thermal expansion can be prevented.

Here, a plurality of the thin film transistors may be provided substantially along a second direction extending along the first surface, and the recessed portion may be formed in a band shape substantially along the second direction. Accordingly, winding of the thin film transistor substrate in a direction substantially orthogonal to an extending direction of the recessed portion is facilitated. Further, the thin film transistor substrate 1 is less liable to curve in the extending direction of the recessed portion, and application of force to the TFT can be suppressed.

Here, the recessed portion may have a substantially rectangular shape in which a side close to the first surface is shorter than a side close to the second surface as taken along a plane extending along the first direction and a plane substantially orthogonal to the second direction. Accordingly, wall surfaces of the recessed portion facing with each other are less liable to abut on each other when the thin film transistor substrate is deformed, and generation of dust can be prevented.

Here, as viewed in the first direction, the flexible substrate may have a thickness at a portion overlapping with the thin film transistor that is twice or more as large as a thickness at a portion in which the recessed portion is formed. Accordingly, the portion in which the recessed portion is formed is easily pliable, and application of force to the TFT can be suppressed.

Here, the flexible substrate may have arc shapes at a boundary portion between the second surface and the recessed portion; and at a bottom end portion of the recessed portion. Accordingly, the thin film transistor substrate is prevented from being chafed by edges when the thin film transistor substrate is wound, for example, and generation of dust can be prevented.

A method for producing a thin film transistor substrate according to one or more embodiments of the present invention include, for example, a first step of forming a recessed portion and a protruding portion in a first surface of a support substrate, a second step of forming a flexible substrate by applying a resin to the first surface to cover the recessed portion and the protruding portion, a third step of forming a thin film transistor in a region which is located in a second surface of the flexible substrate opposite to a surface provided with the support substrate and in which the protruding portion is not formed at the first step, and a fourth step of detaching the flexible substrate from the support substrate.

According to the method for producing a thin film transistor according to one or more embodiments of the present invention, the recessed portion and the protruding portion are formed in the first surface of the support substrate, and the flexible substrate is formed by applying the resin to the first surface to cover the recessed portion and the protruding portion. Accordingly, the recessed portion can be formed in the flexible substrate without performing additional processing. Further, a shape of the recessed portion of the flexible substrate can easily be formed into a substantially rectangular shape in which the side close to the first surface is shorter than the side close to the second surface.

Here, the protruding portion may be formed in a band shape at the first step, and a plurality of the thin film transistors may be formed substantially along a longitudinal direction of the protruding portion at the third step. Accordingly, the recessed portion of the flexible substrate can be in a band shape, and the TFT can be formed at a position not overlapping with the recessed portion of the flexible substrate.

Here, arc shapes may be formed at corner portions of the recessed portion and the protruding portion at the first step. Accordingly, the arc shapes can be formed in the recessed portion of the flexible substrate without performing additional processing.

Here, an alignment mark may be formed in the first surface at the first step, and the thin film transistor may be formed in accordance with the alignment mark at the third step. Accordingly, positions of the protruding portion and the recessed portion, that is, a position at which the TFT is to be formed can be grasped at the time of forming the TFT.

Here, an alignment mark may be formed in the second surface at the second step, and the thin film transistor may be formed in accordance with the alignment mark at the third step. Accordingly, positions of the protruding portion and the recessed portion, that is, a position at which the TFT is to be formed can be grasped at the time of forming the TFT.

According to one or more embodiments of the present invention, cracking or chipping in a substrate can be prevented while improving durability of a TFT with respect to external force caused by bending, winding, and the like.

### BRIEF DESCRIPTION OF DRAWINGS

FIG. 1 is a perspective view illustrating an outline of a thin film transistor substrate 1 according to a first embodiment.

FIG. 2A is a view illustrating arrangement of sub-pixels 10 in the thin film transistor substrate 1, and FIG. 2B is a partially enlarged view of FIG. 2A.

FIG. 3 is a schematic cross-sectional view illustrating the thin film transistor substrate 1.

FIG. 4 is a schematic view illustrating a state in which the thin film transistor substrate 1 is curved.

FIGS. 5A and 5B are explanatory views illustrating arrangement of thin portions 24 of the thin film transistor substrate 1, FIG. 5A is a side view illustrating an outline of a flexible substrate 20, and FIG. 5B is a front view illustrating an outline of the flexible substrate 20.

FIG. 6 is a flowchart illustrating a flow of a method for producing the thin film transistor substrate 1.

FIG. 7 is a schematic view illustrating a state of the thin film transistor substrate 1 during a producing process.

FIG. 8 is a schematic view illustrating a state of the thin film transistor substrate 1 during a producing process.

FIG. 9 is a schematic view illustrating a state of the thin film transistor substrate 1 during a producing process.

FIG. 10 is a schematic view illustrating a state of the thin film transistor substrate 1 during a producing process.

FIG. 11 is a schematic view illustrating a state of the thin film transistor substrate 1 during a producing process.

FIG. 12 is a schematic view illustrating a state of the thin film transistor substrate 1 during a producing process.

### DESCRIPTION OF EMBODIMENTS

Hereinafter, with reference to the drawings, detailed description will be made on embodiments of the present invention. A thin film transistor substrate according to the present invention is a substrate used for a flexible display that can be wound or bent and drives the flexible display. Liquid crystal or organic EL can be used as the flexible display. However, hereinafter, description will be made by exemplifying a flexible display using organic EL.

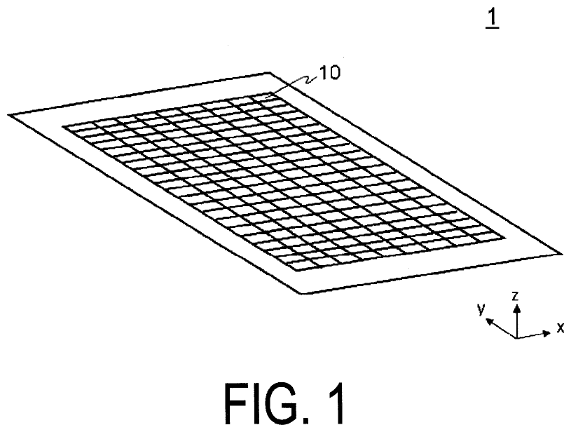

FIG. 1 is a perspective view illustrating an outline of a thin film transistor substrate 1 according to a first embodiment. The thin film transistor substrate 1 has a sheet like shape, and a plurality of sub-pixels 10 are formed in the thin film transistor substrate 1. The plurality of sub-pixels 10 are provided substantially along a plane direction (an x-direction and a y-direction) of the thin film transistor substrate 1. Note that the positions and the arrangement of the sub-pixels 10 illustrated in FIG. 1 are examples and are not limited to those illustrated in FIG. 1.

Pixels of a flexible display (not illustrated) includes three types of the sub-pixels 10. Those three types of sub-pixels include organic EL element layers (not illustrated) emitting red light, blue light, and green light, respectively.

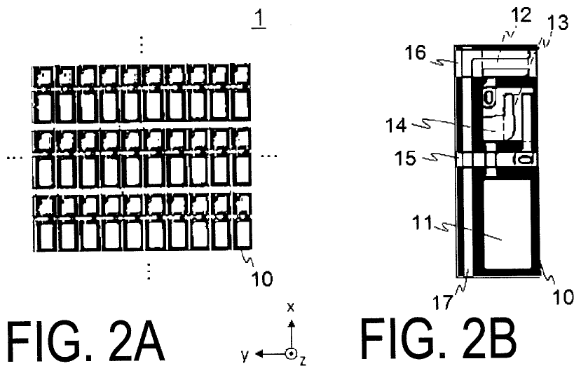

FIG. 2A is a view illustrating arrangement of the sub-pixels 10 in the thin film transistor substrate 1, and FIG. 2B is a partially enlarged view of FIG. 2A.

The sub-pixels 10 are disposed substantially along the x-direction and the y-direction in a lattice-like manner. The sub-pixels 10 mainly each include a pixel electrode 11, thin film transistors (TFTs) 12 and 13, and a holding capacitor 14. Further, wiring lines 15, 16, and 17 are formed inside the sub-pixel 10 and between the sub-pixels 10 adjacent to each other. Note that the configuration and the arrangement of the sub-pixels 10 illustrated in FIGS. 2A and 2B are examples and are not limited to those illustrated in FIGS. 2A and 2B.

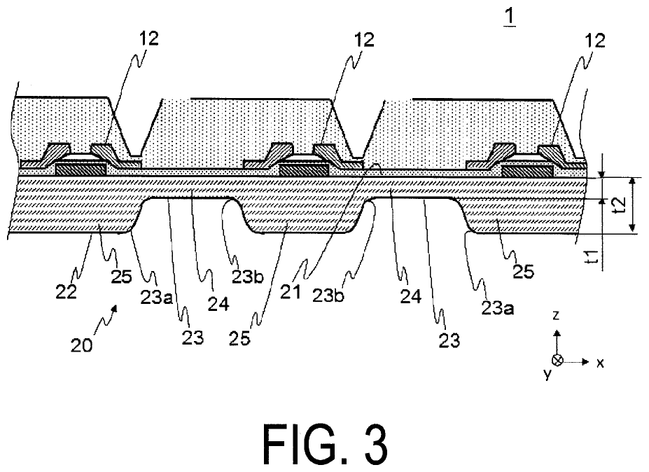

FIG. 3 is a schematic cross-sectional view illustrating the thin film transistor substrate 1. The thin film transistor substrate 1 includes a flexible substrate 20. The flexible substrate 20 is formed of, for example, a resin cured by energy supply, such as a photocurable resin and a thermosetting resin. In the present embodiment, a polyimide resin is used for the flexible substrate 20.

The TFTs 12 and 13 electrically connected to wiring lines (not illustrated) are provided in a front surface 21 of the flexible substrate 20. Note that, in FIG. 3, of the TFTs 12 and 13 provided in the sub-pixels 10, only the TFTs 12 are illustrated, and illustration of the TFTs 13 is omitted.

A plurality of recessed portions 23 are formed in a back surface 22 of the flexible substrate 20. The recessed portions 23 each have a substantially rectangular shape in which a side close to the front surface 21 is shorter than a side close to the back surface 22 as taken along a plane extending along the x-direction and a z-direction (a direction substantially orthogonal to the x-direction and the y-direction). Arc shapes 23a and 23b are formed at a boundary portion between the back surface 22 and the recessed portion 23; and at a bottom end portion of the recessed portion 23, respectively.

The recessed portions 23 are formed, and accordingly the flexible substrate 20 includes thin portions 24 having a thickness smaller than thick portions 25. A thickness t2 of each of the thick portions 25 is twice or more as large as a thickness t1 of each of the thin portions 24. The recessed portions 23 are disposed at positions not overlapping with the TFTs 12 as viewed in the z-direction.

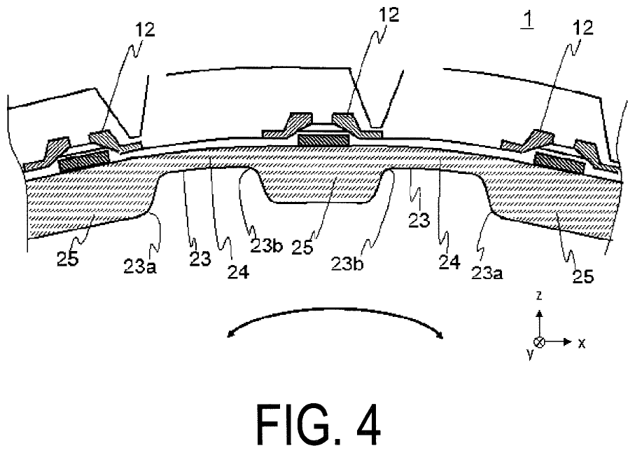

FIG. 4 is a schematic view illustrating a state in which the thin film transistor substrate 1 is curved. When the thin film transistor substrate 1 is curved, the thin portions 24 are bent first, and curvature of the thick portions 25 is suppressed. Further, when the thin film transistor substrate 1 is curved, the thin portions 24 significantly deform, and the deformation of the thick portions 25 is suppressed. As a result, application of force to the TFTs 12 provided in upper sides of the thick portions 25 can be suppressed.

Further, the arc shapes 23b are formed, and thus cracking or the like can be prevented from occurring in the flexible substrate 20 when the thin film transistor substrate 1 is bent and force is concentrated in the corner portions of the recessed portions 23. Moreover, the arc shapes 23a are formed, and thus, when the thin film transistor substrate 1 is wound, dust created by edges chafing a surface of the flexible display (not illustrated) can be prevented from being generated.

Note that FIG. 4 illustrates a state in which the thin film transistor substrate 1 is curved in a direction in which an interval between the TFTs 12 adjacent to each other increases, but the thin film transistor substrate 1 can also be bent in a direction in which the interval between the TFTs 12 adjacent to each other decreases.

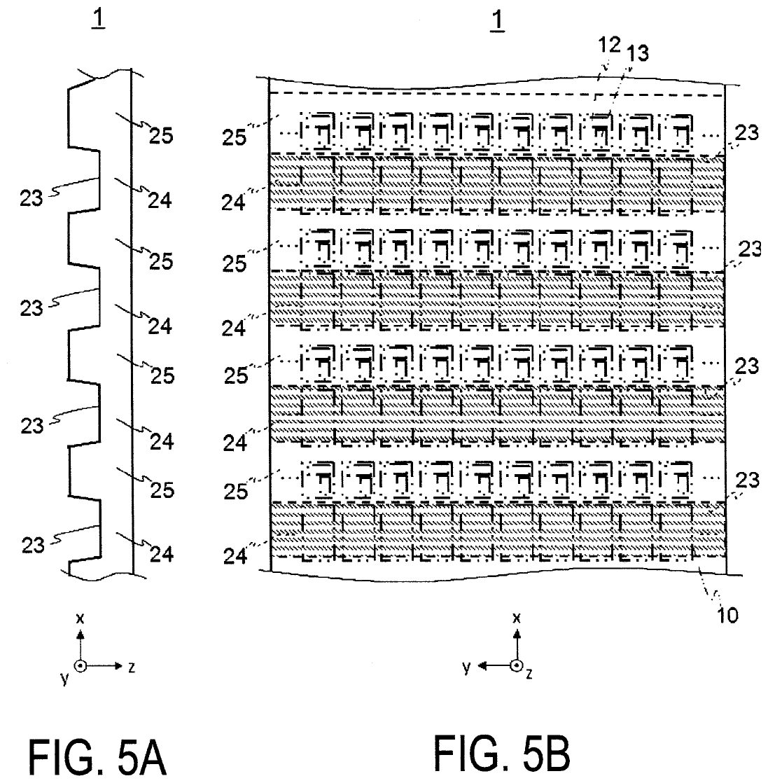

FIGS. 5A and 5B are explanatory views illustrating arrangement of the recessed portions 23 in the thin film transistor substrate 1, FIG. 5A is a side view illustrating an outline of the flexible substrate 20, and FIG. 5B is a front view illustrating an outline of the flexible substrate 20. In FIG. 5B, positions at which the sub-pixels 10 are formed are indicated by dashed-double dotted lines. Further, in FIG. 5B, positions of the recessed portions 23 are hatched.

The TFTs 12 and 13 are disposed substantially along the y-direction. The recessed portions 23 are formed in a band shape substantially along the y-direction at the positions not overlapping with the TFTs 12 and 13. As a result, the flexible substrate 20 (that is, the thin film transistor substrate 1) can be wound in a direction substantially orthogonal to the extending direction of the recessed portions 23, that is, in the x-direction (see an arrow in FIG. 4). Further, the recessed portions 23, that is, the thick portions 25 are formed in a band shape substantially along the y-direction, and thus the thin film transistor substrate 1 is less liable to be curved in the y-direction, and application of force to the TFTs 12 and 13 can be suppressed.

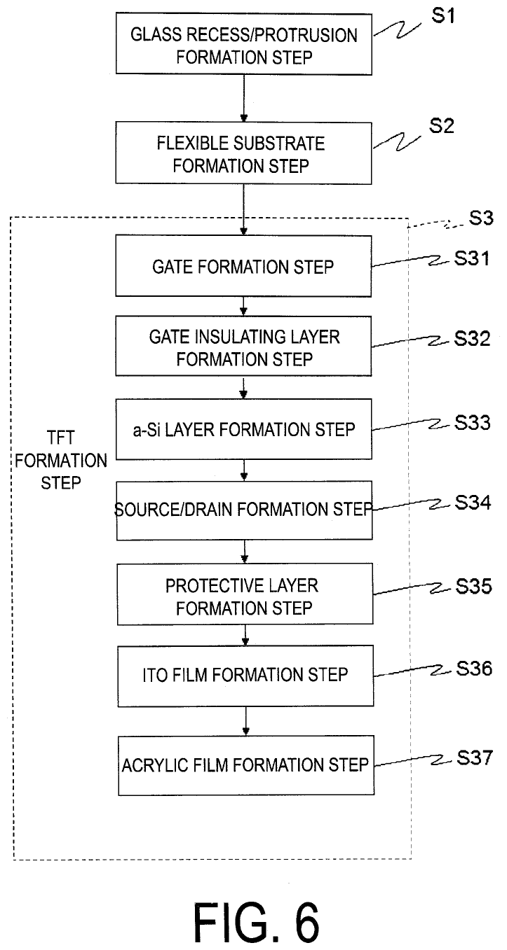

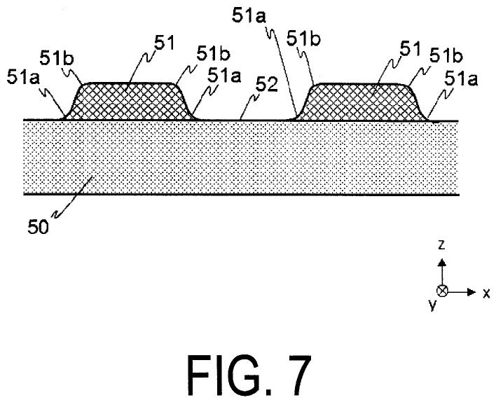

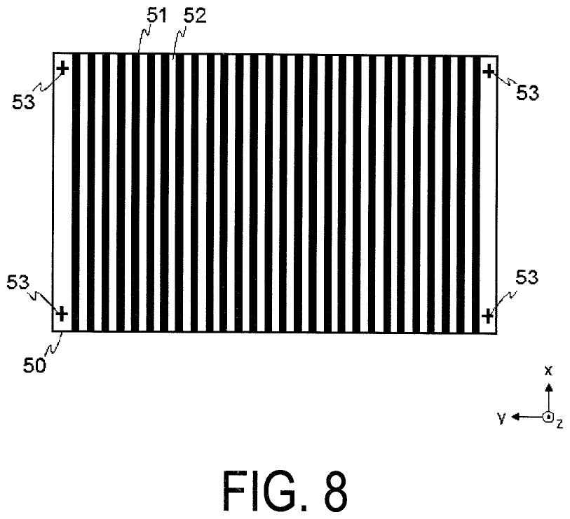

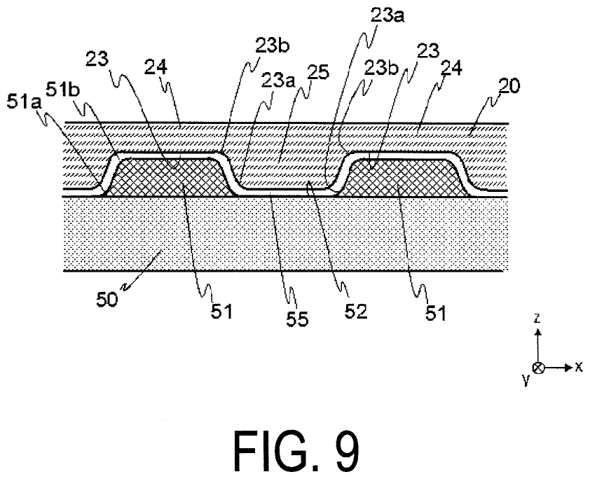

Next, description will be made on a method for producing the thin film transistor substrate 1 according to the present embodiment. FIG. 6 is a flowchart illustrating a flow of the method for producing the thin film transistor substrate 1. Each of FIG. 7 to FIG. 12 is a schematic view illustrating a state of the thin film transistor substrate 1 during a producing process. Each of FIG. 7, and FIG. 9 to FIG. 12 is a cross-sectional view taken along a plane extending along an x-z plane and is a partially enlarged view. FIG. 8 is a plane view.

### Carrier Glass Preparation Step: Step S1

A support substrate is prepared for producing the thin film transistor substrate 1. In the present embodiment, a carrier glass 50 is used as a support substrate.

As illustrated in FIG. 7, protruding portions 51 and recessed portions 52 are formed in an upper surface of the carrier glass 50. As a method for forming the protruding portions 51 and the recessed portions 52, for example, a method for forming the protruding portions 51 by subjecting the carrier glass 50 to printing; a method for forming the recessed portions 52 by shaving the upper surface of the carrier glass 50 with etching or the like; or the like is conceivable. The printing is performed by applying a resin to the carrier glass 50.

In the present embodiment, the protruding portions 51 are printed on the upper surface of the carrier glass 50, and accordingly recesses and protrusions are formed in the upper surface of the carrier glass 50. In the upper surface of the carrier glass 50, portions which are not subjected to printing are the recessed portions 52. The protruding portions 51 are each formed to have corner portions being arc shapes 51a and 51b.

As illustrated in FIG. 8, the protruding portions 51 are formed in a band shape substantially along the y-direction. Further, when the protruding portions 51 are printed in the carrier glass 50, alignment marks 53 are printed in the upper surface of the carrier glass 50. In the present embodiment, the alignment marks 53 each have a substantially cross-like shape, but the shape of the alignment mark 53 is not limited to such a shape. Further, the positions of the alignment marks 53 are also not limited to those positions.

### Flexible Substrate Formation Step: Step S2

As illustrated in FIG. 9, a resin that is formed into the flexible substrate 20 is applied to the upper surface (a surface on the +z side) of the carrier glass 50 to cover the protruding portions 51 and the recessed portions 52, and the flexible substrate 20 is formed. In the present embodiment, first, a resin that is formed into an adhesive layer 55 is applied to the upper surface of the carrier glass 50, and a resin (in this case, a polyimide resin) that is formed into the flexible substrate 20 is applied on the resin that is formed into the adhesive layer 55.

The adhesive layer 55 enables the flexible substrate 20 to come off from the carrier glass 50 easily after production, and various resin materials can be used. Note that the adhesive layer 55 is not necessarily required.

As the resin that is formed into the adhesive layer 55; and the polyimide resin, a resin in a solution form is used. A step of applying a resin in a solution form onto the carrier glass 50 can be performed by using, for example, a coating method such as spin coating and a printing method such as screen printing. After the application, the adhesive layer 55 and the flexible substrate 20 are cured. A curing method differs depending on a resin (photo-curing, thermosetting, and the like). The polyimide resin is a photocurable resin, and thus irradiation with light is performed to cure the polyimide resin in the present embodiment. Accordingly, the flexible substrate 20 is formed in the carrier glass 50.

The protruding portions 51 and the recessed portions 52 are formed in the upper surface of the carrier glass 50, and thus recesses and protrusions are formed in a back surface of the flexible substrate 20 by applying and curing a polyimide resin to flatten a front surface (a surface on the side opposite to the carrier glass 50). The portions of the protruding portions 51 correspond to the recessed portions 23, and the portions applied onto the upper sides of the protruding portions 51 correspond to the thin portions 24. Further, the portions applied onto the upper sides of the recessed portions 52 correspond to the thick portions 25.

Further, the arc shapes 51a and 51b are formed at the corner portions of the protruding portions 51, and thus the arc shapes 23a and 23b are formed in the recessed portions 23.

### TFT Formation Step: Step S3

The TFTs 12 and 13 are formed in the upper side of the flexible substrate 20. Note that, a foundation layer may be formed in the upper side of the flexible substrate 20, and the TFTs may be formed on the foundation layer. A technique that has already been known can be used at the TFT formation step (step S3), and thus details of each step will be omitted.

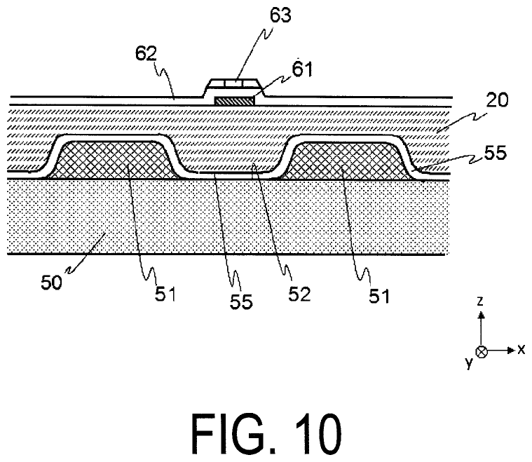

First, a gate electrode 61 is formed in the upper side of the flexible substrate 20, and a gate insulating layer 62 is formed on the gate electrode 61 (see step S31, step S32 in FIG. 6, and FIG. 10). At this time, a portion of wiring lines (a power-source line or a selection line) may be formed.

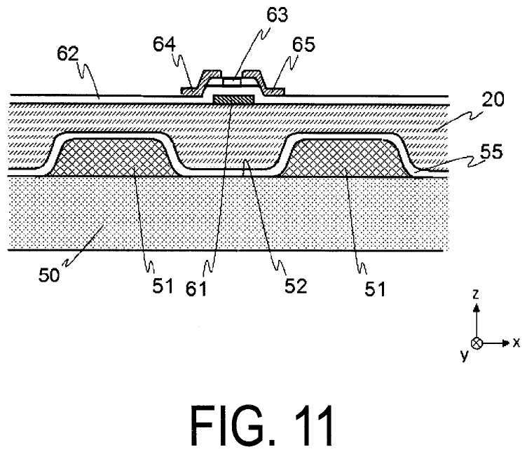

Subsequently, an a-Si layer is formed on the gate insulating layer 62, and the a-Si layer is irradiated with a laser beam to perform dehydrogenation treatment and also to crystallize amorphous silicon (laser annealing). Accordingly, a polycrystalline silicon (p-Si) layer 63 is obtained (see step S33 in FIG. 6 and FIG. 10). A source electrode 64 and a drain electrode 65 are formed on the p-Si layer 63 (see step S34 in FIG. 6 and FIG. 11). At this time, a portion of wiring lines (a data line) may be formed.

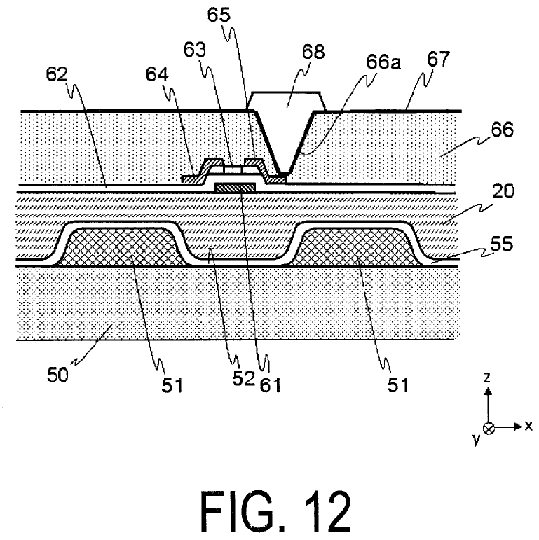

Next, a TFT protective layer 66 is formed (see step S35 in FIG. 6 and FIG. 12), and an ITO film (a transparent electrode film) 67 is formed on the TFT protective layer 66 (see step S36 in FIG. 6 and FIG. 12). An organic resin can be used as the TFT protective layer 66. A recessed portion 66a is formed in the TFT protective layer 66, and the ITO film 67 abuts on the drain electrode 65. Subsequently, an acrylic resin 68 is injected in a space formed by the recessed portion 66a (see step S37 in FIG. 6 and FIG. 12).

Accordingly, the TFT formation step (step S3) ends. At the TFT formation step (step S3), the plurality of TFTs are formed substantially along the longitudinal direction (the y-direction) of the protruding portions 51 in regions where the protruding portions 51 are not formed at the carrier glass preparation step (step S1).

At the TFT formation step (step S3), the TFTs are formed in accordance with the alignment marks 53 formed at the carrier glass preparation step (step S1). The positions of the protruding portions 51 with respect to the positions of the alignment marks 53 are known in advance, and thus the positions at which the TFTs are to be formed are found by referring to the alignment marks 53 even when the positions of the protruding portions 51 are not visually recognized.

The thin film transistor substrate 1 is formed by the steps described above. After the thin film transistor substrate 1 is formed, an organic EL film is formed and sealed, and then the flexible substrate 20 is detached from the carrier glass 50.

Note that in the present embodiment, the alignment marks 53 are formed at the carrier glass preparation step (step S1); however, the alignment marks 53 may not be formed at the carrier glass preparation step (step S1), and after the flexible substrate 20 is formed at the flexible substrate formation step (step S2), alignment marks may be formed in a surface (+z side surface) opposite to the surface provided with the carrier glass 50 of the flexible substrate 20. In this case, the alignment marks are easily recognized at the TFT formation step (step S3). Therefore, there is an advantage of facilitating formation of the TFTs in accordance with the alignment marks.

According to the present embodiment, the TFTs 12 and 13 are formed in the flexible substrate 20, and the recessed portions 23, that is, the thin portions 24 are formed at the positions not overlapping with the TFTs 12 and 13 as viewed in the z-direction. Thus, durability of the TFTs with respect to external force due to curvature, winding, and the like of the substrate can be improved.

Further, in the present embodiment, the thin portions 24 and the thick portions 25 are formed by varying the thickness of the flexible substrate 20, and thus generation of internal stress due to deformation of the thin film transistor substrate 1 or change in temperature can be prevented. For example, in a case where a thin film transistor substrate is formed by providing a member that decreases flexibility in the flexible substrate 20, it is necessary to bond members formed of different materials, thus internal stress is generated due to a difference in a coefficient of thermal expansion or the like, and there is a risk of generation of cracking or chipping in the thin film transistor substrate.

Further, a coefficient of thermal expansion differs depending on the members, and accordingly there is a risk of generation of creases or deformation in the thin film transistor substrate. In contrast, in the present embodiment, only one type of material is used for the flexible substrate 20, and thus such defects can be prevented.

Further, according to the present embodiment, the recessed portions 23 are formed in a band shape substantially along the y-direction. Accordingly, deformation of the thin film transistor substrate 1 such as winding and bending in the x-direction is facilitated and can improve usability as a flexible display. Further, the thickness t2 of the thick portion 25 is twice or more as large as the thickness t1 of the thin portion 24, and thus deformation of the thick portions 25, that is, application of force to the TFTs 12 and 13 can be suppressed.

Further, according to the present embodiment, the arc shapes 23a and 23b are formed at the corner portions of the thin portions 24 and the thick portions 25, and thus, for example, when the thin film transistor substrate 1 is wound, the thin film transistor substrate 1 is not chafed by edges. Further, as taken along the plane extending along the x-direction and the z-direction, the side of the recessed portion 23 that is close to the front surface 21 is shorter than the side close to the back surface 22, and thus when the thin film transistor substrate 1 is deformed substantially along the x-direction, the wall surfaces facing with each other of the recessed portions 23 are less liable to abut on each other, and generation of dust can be prevented.

Further, according to the present embodiment, when the thin film transistor substrate 1 is produced, the protruding portions 51 and the recessed portions 52 are formed in the upper surface of the carrier glass 50 (step S1), and a resin film that is formed into the flexible substrate 20 is formed in the upper surface of the carrier glass 50 to cover the protruding portions 51 and the recessed portions 52 (step S2). Thus, the thin portions 24 and the thick portions 25 can be formed in the flexible substrate 20 without subjecting the flexible substrate 20 to additional processing. Further, the thin film transistor substrate 1 is produced in the above-described manner, accordingly, the shape of the recessed portion 23 as taken along the plane extending along the x-direction and the z-direction is easily formed into a substantially rectangular shape in which the side close to the front surface 21 is shorter than the side close to the back surface 22, and the arc shapes 23a and 23b are easily formed at the corner portions of the thin portions 24 and the thick portions 25.

Further, the alignment marks are formed in the upper surface of the carrier glass 50 or the flexible substrate 20, and accordingly the positions of the protruding portions 51 and the recessed portions 52, that is, the positions at which the TFTs are to be formed can be grasped at the time of forming the TFTs.

Note that in the present embodiment, the bottom gate-type TFTs each including the source electrode 64 and the drain electrode 65 formed in an upper side of the gate electrode 61 (a side opposite to the flexible substrate 20); however, top gate-type TFTs each including the gate electrode 61 formed in upper sides of the source electrode 64 and the drain electrode 65 may be formed.

Further, in the present embodiment, description is made on the example where the organic EL is provided on the thin film transistor substrate 1. However, in a case where liquid crystal is provided on the thin film transistor substrate 1, some of the steps become unnecessary. For example, the foundation layer formed in the upper side of the flexible substrate 20, particularly, a gas barrier layer is unnecessary. Further, the shape of the TFT protective layer 66 is also different, and thus the step of injecting the acrylic resin 68 (step S37) is also unnecessary.

Further, in the present embodiment, the thin portions 24 and the thick portions 25 are formed in a band shape substantially along the y-direction, but the arrangement of the thin portions 24 and the thick portions 25 is not limited to such arrangement. For example, the thick portions 25 may be formed in a band shape by forming the thick portions 25 having a substantially rectangular shape at positions overlapping with the TFTs 12 and 13 as viewed in the z-direction and disposing the thick portions 25 adjacent to each other substantially along the y-direction. Further, in the present embodiment, the TFTs 12 and 13 are disposed substantially along the y-direction, but the arrangement of the TFTs 12 and 13 is not limited to such arrangement. For example, the TFTs 12 and 13 may be disposed in a staggered manner.

The embodiments of the invention are described above in detail with reference to the drawings. However, specific configurations are not limited to the embodiments, and also include changes in the design or the like within a scope that does not depart from the gist of the invention.

Further, the term “substantially” in the present invention is a concept not only including the case of being strictly the same, but also including deviations and modifications to an extent that does not result in loss in identity. For example, the term “substantially rectangular shape” is not limited to the case of being strictly a rectangular shape. Further, for example, the case where the expression “along the y-direction” is simply given not only includes the case of extending strictly along the y-direction, but also the case of extending substantially along the y-direction, for example, the case of extending along a direction deviated from the y-direction by a few degrees.

### REFERENCE SIGNS LIST

1 Thin film transistor substrate
10 Sub-pixel
11 Pixel electrode
12, 13 TFT
14 Holding capacitor
15, 16, 17 Wiring line
20 Flexible substrate
21 Front surface
22 Back surface
23 Recessed portion
23a, 23b Arc shape
24 Thin portion
25 Thick portion
50 Carrier glass
51 Protruding portion
51a, 51b Arc shape
52 Recessed portion
53 Alignment mark
55 Adhesive layer
61 Gate electrode
62 Gate insulating layer
63 Polycrystalline silicon layer
64 Source electrode
65 Drain electrode
66 TFT protective layer
66a Recessed portion
67 ITO film
68 Acrylic resin

1. A thin film transistor substrate comprising:
a flexible substrate; and
a thin film transistor provided in a first surface of the flexible substrate, wherein
a recessed portion is formed in a second surface opposite to the first surface of the flexible substrate, and
the recessed portion is disposed at a position not overlapping with the thin film transistor as viewed in a first direction substantially orthogonal to the first surface.

2. The thin film transistor substrate according to claim 1, wherein
a plurality of the thin film transistors are provided substantially along a second direction extending along the first surface,
the recessed portion is formed in a band shape substantially along the second direction.

3. The thin film transistor substrate according to claim 2, wherein the recessed portion has a substantially rectangular shape in which a side close to the first surface is shorter than a side close to the second surface as taken along a plane extending along the first direction and a plane substantially orthogonal to the second direction.

4. The thin film transistor substrate according to claim 1, wherein, as viewed in the first direction, the flexible substrate has a thickness at a portion overlapping with the thin film transistor that is twice or more as large as a thickness at a portion in which the recessed portion is formed.

5. The thin film transistor substrate according to claim 1, wherein the flexible substrate has arc shapes at a boundary portion between the second surface and the recessed portion; and at a bottom end portion of the recessed portion.

6. A method for producing a thin film transistor substrate, the method comprising:
a first step of forming a recessed portion and a protruding portion in a first surface of a support substrate;
a second step of forming a flexible substrate by applying a resin to the first surface to cover the recessed portion and the protruding portion;
a third step of forming a thin film transistor in a region which is located in a second surface of the flexible substrate opposite to a surface provided with the support substrate and in which the protruding portion is not formed at the first step; and
a fourth step of detaching the flexible substrate from the support substrate.

7. The method for producing a thin film transistor substrate according to claim 6, wherein
the protruding portion is formed in a band shape at the first step, and
a plurality of the thin film transistors are formed substantially along a longitudinal direction of the protruding portion at the third step.

8. The method for producing a thin film transistor substrate according to claim 6, wherein arc shapes are formed at corner portions of the recessed portion and the protruding portion at the first step.

9. The method for producing a thin film transistor substrate according to claim 6, wherein
an alignment mark is formed in the first surface at the first step, and
the thin film transistor is formed in accordance with the alignment mark at the third step.

10. The method for producing a thin film transistor substrate according to claim 6, wherein
an alignment mark is formed in the second surface at the second step, and
the thin film transistor is formed in accordance with the alignment mark at the third step.

11. The thin film transistor substrate according to claim 2, wherein, as viewed in the first direction, the flexible substrate has a thickness at a portion overlapping with the thin film transistor that is twice or more as large as a thickness at a portion in which the recessed portion is formed.

12. The thin film transistor substrate according to claim 3, wherein, as viewed in the first direction, the flexible substrate has a thickness at a portion overlapping with the thin film transistor that is twice or more as large as a thickness at a portion in which the recessed portion is formed.

13. The thin film transistor substrate according to claim 2, wherein the flexible substrate has arc shapes at a boundary portion between the second surface and the recessed portion; and at a bottom end portion of the recessed portion.

14. The thin film transistor substrate according to claim 3, wherein the flexible substrate has arc shapes at a boundary portion between the second surface and the recessed portion; and at a bottom end portion of the recessed portion.

15. The thin film transistor substrate according to claim 4, wherein the flexible substrate has arc shapes at a boundary portion between the second surface and the recessed portion; and at a bottom end portion of the recessed portion.

16. The method for producing a thin film transistor substrate according to claim 7, wherein arc shapes are formed at corner portions of the recessed portion and the protruding portion at the first step.

17. The method for producing a thin film transistor substrate according to claim 7, wherein
an alignment mark is formed in the first surface at the first step, and
the thin film transistor is formed in accordance with the alignment mark at the third step.

18. The method for producing a thin film transistor substrate according to claim 8, wherein
an alignment mark is formed in the first surface at the first step, and the thin film transistor is formed in accordance with the alignment mark at the third step.

19. The method for producing a thin film transistor substrate according to claim 7, wherein
an alignment mark is formed in the second surface at the second step, and
the thin film transistor is formed in accordance with the alignment mark at the third step.

20. The method for producing a thin film transistor substrate according to claim 8, wherein
an alignment mark is formed in the second surface at the second step, and
the thin film transistor is formed in accordance with the alignment mark at the third step.
